(19) United States
(12) Patent Application Publication
(10) Pub. No.: US 2015/0257270 A1
(43) Pub. Date: Sep. 10, 2015

(54) STRUCTURE

(71) Applicant: SHARP KABUSHIKI KAISHA, Osaka-shi (JP)

(72) Inventors: Toshinori Kondo, Osaka-shi (JP); Hiroyuki Takebe, Osaka-shi (JP)

(73) Assignee: SHARP KABUSHIKI KAISHA, Osaka-shi (JP)

(21) Appl. No.: 14/428,221

(22) PCT Filed: Oct. 15, 2013
(86) PCT No.: PCT/JP2013/077968

§ 371 Date: Mar. 13, 2015

(30) Foreign Application Priority Data
Nov. 28, 2012 (JP) 2012-260134

(51) Int. Cl. H05K 1/16; H01Q 1/38

(52) U.S. Cl. CPC H05K 1/16; H01Q 1/38

(57) ABSTRACT

A structure includes a circuit board; another circuit board provided so as not to face the circuit board; and an electrically conductive pattern provided on a housing having no flexibility, the electrically conductive pattern electrically connecting the circuit board and the another circuit board.

### TECHNICAL FIELD

The present invention relates to a structure including an electrically conductive pattern that electrically connects a circuit board and an electrically conductive section.

### BACKGROUND ART

There is disclosed a technique for causing a contact spring or the like to electrically connect a board and a sheet metal. For example, Patent Literature 1 discloses a structure in which a circuit board and a sheet metal are provided so as to face each other and a contact spring terminal mounted on the circuit board and a part of the sheet metal are in contact with each other by being provided so as to face each other.

### CITATION LIST

### Patent Literatures

Patent Literature 1

Japanese Patent Application Publication, Tokukai, No. 2009-212977 A (Publication Date: Sep. 17, 2009)

Patent Literature 2

Japanese Patent Application Publication, Tokukai, No. 2009-33681 A (Publication Date: Feb. 12, 2009)

### SUMMARY OF INVENTION

### Technical Problem

However, according to such a conventional technique as described above, a circuit board and a sheet metal cannot be connected by use of a contact spring in a case where the circuit board and the sheet metal do not face each other, e.g., in a case where the circuit board and the sheet metal are aligned so as to be flush with each other, or a case where another member that is different from the circuit board and the sheet metal is provided between the circuit board and the sheet metal. This causes a problem such that it is impossible to maintain electric connection between the circuit board and the sheet metal.

The present invention has been made in view of the problem, and a main object of the present invention is to provide a structure that makes it possible to suitably electrically connect a circuit board and an electrically conductive section also in a case where the electrically conductive section such as a sheet metal is provided so as not to face the circuit board.

### Solution to Problem

In order to attain the object, a structure in accordance with an embodiment of the present invention includes a circuit board; an electrically conductive section provided so as not to face the circuit board; and an electrically conductive pattern provided on an insulator having no flexibility, the electrically conductive pattern electrically connecting the circuit board and the electrically conductive section.

### Advantageous Effects of Invention

According to an aspect of the present invention, it is possible to yield an effect of suitably electrically connecting a circuit board and an electrically conductive section also in a case where the electrically conductive section is provided so as not to face the circuit board.

### BRIEF DESCRIPTION OF DRAWINGS

FIG. 1 shows an example of a structure in accordance with an embodiment (Embodiment 1) of the present invention. (a) of FIG. 1 is a top view of the structure, and (b) of FIG. 1 is a cross-sectional view taken from line A-A′ of (a) of FIG. 1.

(a) of FIG. 2 and (b) of FIG. 2 each show another example of the structure in accordance with the embodiment (Embodiment 1) of the present invention.

FIG. 3 shows an example of a structure in accordance with an embodiment (Embodiment 2) of the present invention. (a) of FIG. 3 is a top view of the structure, and (b) of FIG. 3 is a cross-sectional view taken from line B-B′ of (a) of FIG. 3.

FIG. 4 shows another example of the structure in accordance with the embodiment (Embodiment 2) of the present invention.

FIG. 5 shows an example of a portable device including the structure in accordance with the embodiment (Embodiment 2) of the present invention.

FIG. 6 shows an example of a structure in accordance with an embodiment (Embodiment 3) of the present invention. (a) of FIG. 6 is a top view of the structure, and (b) of FIG. 6 is a cross-sectional view taken from line C-C′ of (a) of FIG. 6.

FIG. 7 shows an example of a structure in accordance with an embodiment (Embodiment 4) of the present invention. (a) of FIG. 7 is a top view of the structure, and (b) of FIG. 7 is a cross-sectional view taken from line D-D′ of (a) of FIG. 7.

FIG. 8 shows another example of the structure in accordance with the embodiment (Embodiment 4) of the present invention.

FIG. 9 shows still another example of the structure in accordance with the embodiment (Embodiment 4) of the present invention.

### DESCRIPTION OF EMBODIMENTS

### Embodiment 1

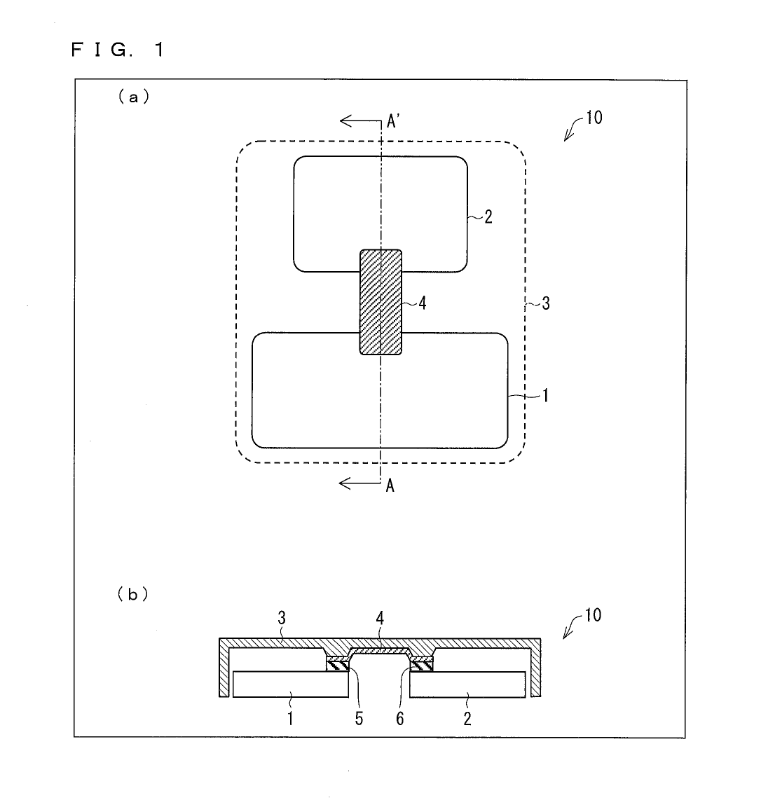

An embodiment of the present invention is specifically described below. FIG. 1 shows an example of a structure in accordance with a first embodiment (Embodiment 1) of the present invention. (a) of FIG. 1 is a top view of the structure, and (b) of FIG. 1 is a cross-sectional view taken from line A-A′ of (a) of FIG. 1.

As illustrated in (a) of FIG. 1 and (b) of FIG. 1, a structure 10 in accordance with Embodiment 1 includes a circuit board 1, a circuit board (electrically conductive section) 2, a housing (insulator) 3, an electrically conductive pattern 4, a gasket 5, and a gasket 6.

The circuit board 1 and the circuit board 2 are electrically conductive members each of which has a surface provided with a circuit pattern. As illustrated in FIG. 1, the circuit board 2 is provided so as to face a surface of the housing 3 which surface faces the circuit board 1, and so as to be located in a place where the circuit board 1 is not provided. Specifically, the circuit board 2 and the circuit board 1 are aligned so as to be flush with each other (see FIG. 1). Note, however, that where to provide the circuit board 2 is not limited to this. The circuit board 2 can be located so as not to be flush with and so as not to face the circuit board 1.

The housing 3 is a member having an insulating property. Further, the housing 3 is a member having no flexibility. The housing 3 is provided so as to surround the circuit board 1, the circuit board 2, and the electrically conductive pattern 4. Note that the housing 3 is not particularly limited in size and shape.

The electrically conductive pattern 4 is a filmy electrically conductive material which is provided on the housing 3 so as to have any shape. Note that the electrically conductive pattern 4 does not need to be provided on the housing 3. Alternatively, the electrically conductive pattern 4 can be provided on an insulator having no flexibility but is not the housing 3.

According to Embodiment 1, the electrically conductive pattern 4 is provided so that the circuit board 1 and the circuit board 2 are ground (GND) connected. This can stabilize respective reference electric potentials of the circuit boards 1 and 2. Note that “A and B are ground connected” herein means that grounds of A and B are connected with each other. In a case where A (B) is merely an electrically conductive material, the ground of A (B) indicates A (B) itself.

Note that the electrically conductive pattern 4 does not need to connect grounds of the circuit board 1 and the circuit board 2. Alternatively, the electrically conductive pattern 4 can connect electric wires of the circuit board 1 and the circuit board 2. That is, the electrically conductive pattern 4 only needs to be provided so as to electrically connect the circuit board 1 and the circuit board 2. In any case, according to Embodiment 1, the electrically conductive pattern 4 does not function by itself but operates only when the circuit board 1 and circuit board 2 are electrically connected.

According to Embodiment 1, the electrically conductive pattern 4 is formed by an LDS (Laser Direct Structuring) method. Note, however, that how to form the electrically conductive pattern 4 is not limited to this. For example, the electrically conductive pattern 4 can be an electrically conductive paint printed pattern obtained by printing electrically conductive paint on the housing 3.

The gasket 5 and the gasket 6 are electrically conductive and elastic members. The gasket 5 connects the circuit board 1 and the electrically conductive pattern 4, and the gasket 6 connects the circuit board 2 and the electrically conductive pattern 4. This allows the circuit board 1 and the circuit board 2 to be electrically connected via the electrically conductive pattern 4. Note that a member which connects the circuit board 1 and the electrically conductive pattern 4 does not need to be the gasket 5 and that a member which connects the circuit board 2 and the electrically conductive pattern 4 does not need to be the gasket 6. Alternatively, each of these members can be an electrically conductive spring or the like. In addition, the circuit board 1 and the electrically conductive pattern 4 can be configured to be directly connected via no gasket 5 or the like. Similarly, the circuit board 2 and the electrically conductive pattern 4 can be configured to be directly connected via no gasket 6 or the like.

As described earlier, the structure 10 in accordance with Embodiment 1 includes the circuit board 1, the circuit board 2 which is provided so as not to face the circuit board 1, and the electrically conductive pattern 4 which is provided on the housing 3 having no flexibility. The electrically conductive pattern 4 electrically connects the circuit board 1 and the circuit board 2.

The pattern 4 provided on the insulator (the housing 3) having no flexibility can be stretched with a high degree of freedom. This is because the insulator can be designed to have any shape. In particular, use of the LDS method to form the electrically conductive pattern 4 makes it possible to obtain the electrically conductive pattern 4 which has a highly accurate shape. Accordingly, as illustrated in FIG. 1, the configuration allows the circuit board 1 and the circuit board 2 to be suitably electrically connected also in a case where the circuit board 2 is provided so as not to face the circuit board 1.

Further, connection of the circuit board 1 and the circuit board 2 by use of copper foil, a flexible printed circuit board, a sheet metal, or the like makes it necessary to provide, in view of a thickness of the copper foil, the flexible printed circuit board, the sheet metal, or the like, and a thickness of an adhesive material (e.g., a double-sided adhesive tape) with which the copper foil, the flexible printed circuit board, the sheet metal, or the like adheres to the housing 3, a space in which the copper foil, the flexible printed circuit board, the sheet metal, or the like, and the adhesive material can be contained. Further, the copper foil, the flexible printed circuit board, the sheet metal, or the like has a disadvantage of, for example, being fragile and less workable.

In contrast, as compared with the copper foil, the flexible printed circuit board, the sheet metal, or the like, the electrically conductive pattern 4 which is used in Embodiment 1 and provided on the housing 3 can be formed in a smaller space and can be more workable. In addition, since the housing 3 on which the electrically conductive pattern 4 is provided has no flexibility, the electrically conductive pattern 4 can be electrically connected with the circuit boards 1 and 2 directly or via elastic bodies such as the gaskets 5 and 6.

In particular, in a case where the electrically conductive pattern 4 in accordance with Embodiment 1 is formed by the LDS method, it is possible to connect the circuit board and the electrically conductive section in a smaller space and at lower cost than in a case where the circuit board and the electrically conductive section are connected by use of copper foil or the like. Further, it is possible to easily form an electrically conductive pattern which has a highly accurate shape that is difficult to make by use of copper foil or the like.

Since it is a matter of course that surroundings of members which are provided in the housing 3 are enclosed with the housing 3, in a case where the electrically conductive pattern 4 is provided on the housing 3, it is possible to easily connect any members by causing the electrically conductive pattern 4 to pass through outsides of the any members. In other words, in a case where the electrically conductive pattern 4 is provided on the housing 3, which surrounds the circuit board 1 and the circuit board 2, it is possible to securely electrically connect the circuit board 1 and the circuit board 2 regardless of a positional relationship between the circuit board 1 and the circuit board 2. Further, also in a case where another member that is different from the circuit board 1 and the circuit board 2 is provided between the circuit board 1 and the circuit board 2, it is possible to securely electrically connect the circuit board 1 and the circuit board 2 by avoiding the another member.

(Modification 1)

(a) of FIG. 2 and (b) of FIG. 2 each show another example of the structure in accordance with the embodiment (Embodiment 1). Note that, for convenience, members having functions identical to those of the respective members described with reference to FIG. 1 are given respective identical reference numerals, and a description of those members is omitted here.

A structure 10′ illustrated in (a) of FIG. 2 is different from the structure 10 of FIG. 1 in that an insulator 3′ on which the electrically conductive pattern 4 is provided is provided so as to partially cover the circuit boards 1 and 2, and to cover the electrically conductive pattern 4. As described earlier, the insulator 3′ only needs to have a size that is large enough for the electrically conductive pattern 4 provided on the insulator 3′ to electrically connect the circuit board 1 and the circuit board 2.

Meanwhile, a structure 10″ illustrated in (b) of FIG. 2 includes two electrically conductive patterns 4′. As described earlier, the number of electrically conductive patterns provided on the housing 3 can be two or more. Further, as illustrated in (b) of FIG. 2, one of the two electrically conductive patterns 4′ has an angular shape. An electrically conductive pattern 4′ can have a linear shape, an angular shape, or another shape. Additionally, the electrically conductive pattern can have any size (length and width) provided that the size allows electric connection between the circuit board 1 and the circuit board 2. For example, the electrically conductive pattern 4 which is made larger and shorter allows more suitable stabilization of a GND.

Furthermore, the electrically conductive pattern 4, which can be changed to have any size and any shape, is capable of suitably electrically connecting the circuit board 1 and the circuit board 2 also in a case where the circuit board 1 and the circuit board 2 are provided so as to be away from each other.

(Modification 2)

Alternatively, the housing 3 of the structure 10 in accordance with Embodiment 1 can be provided with an antenna pattern which is formed as in the case of the electrically conductive pattern 4. In a case where the antenna pattern is formed as in the case of the electrically conductive pattern 4, it is possible to achieve, for example, a space saving, lower cost, and a reduction in number of components, as compared with a case where the antenna pattern and the electrically conductive pattern 4 are formed in respective different methods. Note that, as in the case of the electrically conductive pattern 4, the insulator on which the antenna pattern is provided is not limited to the housing 3.

### Embodiment 2

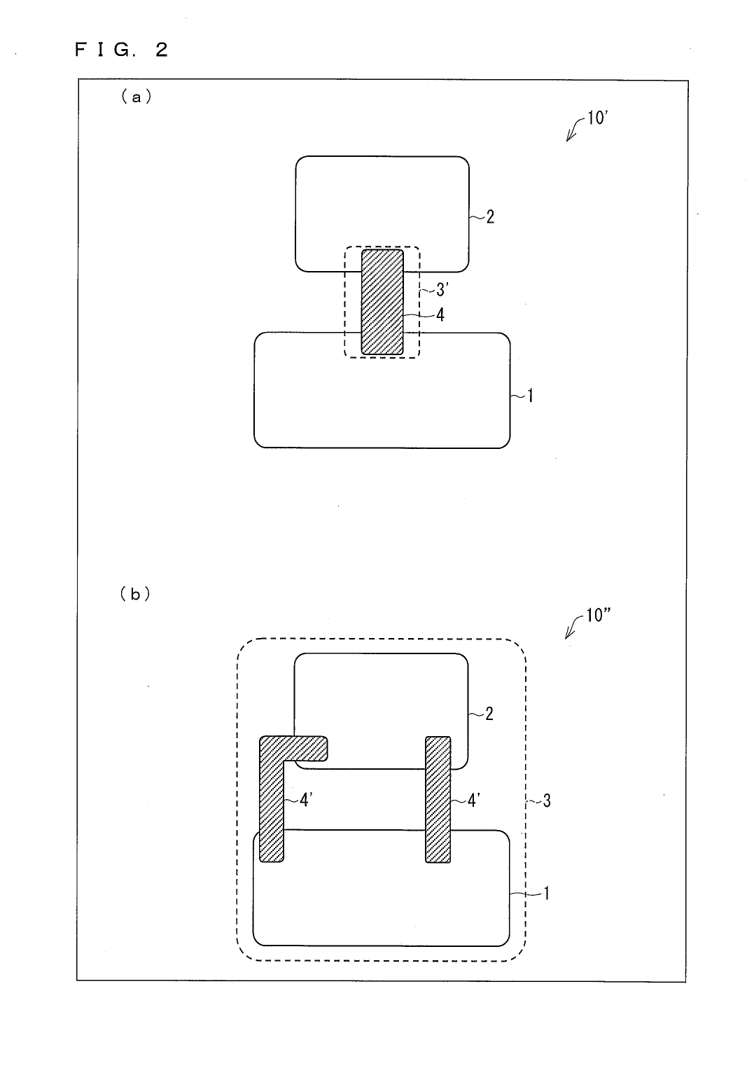

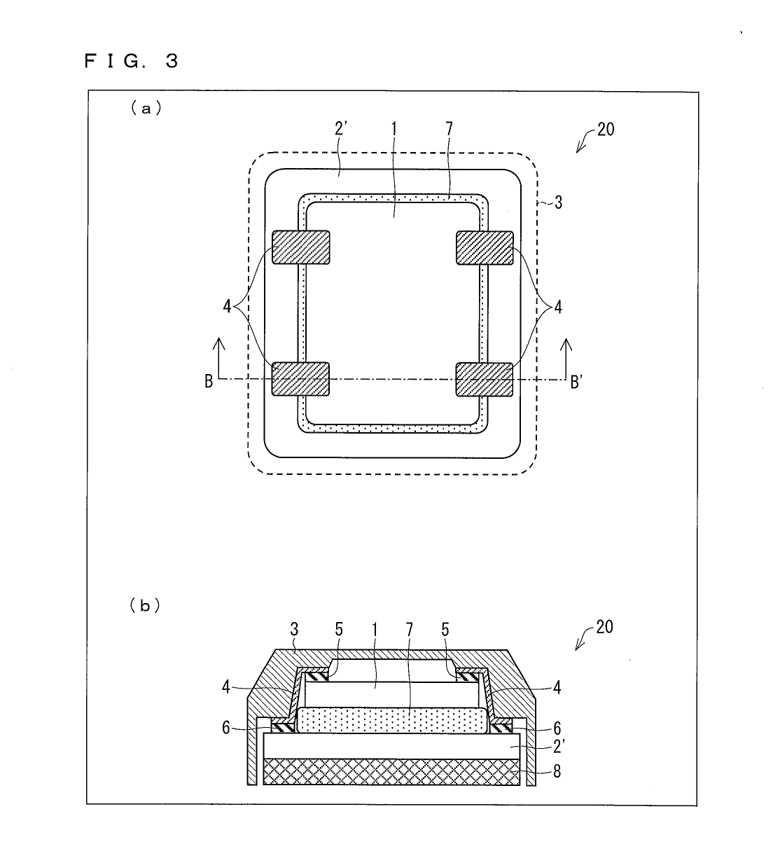

FIG. 3 shows an example of a structure in accordance with another embodiment (Embodiment 2) of the present invention. (a) of FIG. 3 is a top view of the structure, and (b) of FIG. 3 is a cross-sectional view taken from line B-B′ of (a) of FIG. 3. Note that, for convenience, members having functions identical to those of the respective members described in Embodiment 1 are given respective identical reference numerals, and a description of those members is omitted here.

As illustrated in (a) of FIG. 3 and (b) of FIG. 3, a structure 20 in accordance with Embodiment 2 includes a circuit board 1, a frame member (electrically conductive section) 2′, a housing (insulator) 3, an electrically conductive pattern 4, a gasket 5, a gasket 6, a battery (spacer member) 7, and an LCD (Liquid Crystal Display) unit 8.

As illustrated in (a) of FIG. 3 and (b) of FIG. 3, Embodiment 2 gives the following description by taking, as an example, a case where four electrically conductive patterns 4 are provided. Note, however, that the number of the electrically conductive patterns 4 is not limited to four.

Further, as illustrated in FIG. 3, the housing 3 is provided so as to surround the circuit board 1, the frame member 2′, the battery 7, and the LCD unit 8.

The frame member 2′, which is electrically conductive, is a frame member for, for example, reinforcing the strength of the LCD unit 8, securing a strength of the structure 20, and preventing unnecessary radiation of noise. The frame member 2′ can be a sheet metal, an Mg frame, a carbon frame, or the like.

Each of the gaskets 5 and 6 can be a spring or the like as in the case of the gaskets 5 and 6 of Embodiment 1. Further, the structure 20 can be configured such that the circuit board 1 and the electrically conductive pattern 4 are directly connected via no gasket 5. Similarly, the structure 20 can also be configured such that the frame member 2′ and the electrically conductive pattern 4 are directly connected via no gasket 6.

The battery 7, which is provided between the circuit board 1 and the frame member 2′, is a member for preventing the circuit board 1 and the frame member 2′ from facing each other. As illustrated in FIG. 3, the battery 7, which has a top surface whose area is larger than that of a bottom surface of the circuit board 1, isolates the circuit board 1 and the frame member 2′ from each other.

Note that a member which is provided between the circuit board 1 and the frame member 2′ and prevents the circuit board 1 and the frame member 2′ from facing each other is not limited to the battery. For example, the member can be a resin holder or the like.

As illustrated in FIG. 3, the circuit board 1 and the frame member 2′ are ground connected via the electrically conductive pattern 4 formed on the housing 3 by, for example, the LDS method or printing of electrically conductive paint (A ground of the circuit board 1 and the frame member 2′ are electrically connected). This allows stabilization of a reference electric potential of the circuit board 1.

Note here that, since use of the LDS method makes it possible to form the electrically conductive pattern by laser irradiation, even the electrically conductive pattern 4 which is three-dimensional as illustrated in (b) of FIG. 3 can be easily formed at low cost. Therefore, the electrically conductive pattern 4 can be formed, with a smaller number of operations and at low cost, in a place where the electrically conductive pattern 4 suitably connects the circuit board 1 and the frame member 2.

Note also that use of the LDS method also makes it possible to easily form even, for example, an electrically conductive pattern having a complicated shape, and an electrically conductive pattern having a thin shape. Thus, an electrically conductive pattern having a more accurate shape can be formed by the LDS method than by, for example, a method in which an electrically conductive pattern is formed by spraying the housing 3 with an electrically conductive coating material.

Also in a case where the battery 7 is provided between the circuit board 1 and the frame member 2′ so as to prevent the circuit board 1 and the frame member 2′ from facing each other (see FIG. 3), the circuit board 1 and the frame member 2′ can be suitably electrically connected by use of the electrically conductive pattern 4 provided on the housing 3.

Conversely, in a case where the circuit board 1 and the frame member 2′ are connected by use of the electrically conductive pattern 4 provided on the housing 3, the battery 7 provided between the circuit board 1 and the frame member 2′ can have a size that is excessively large enough to prevent the circuit board 1 and the frame member 2′ from facing each other. This allows an increase in capacitance of the battery 7.

(Modification)

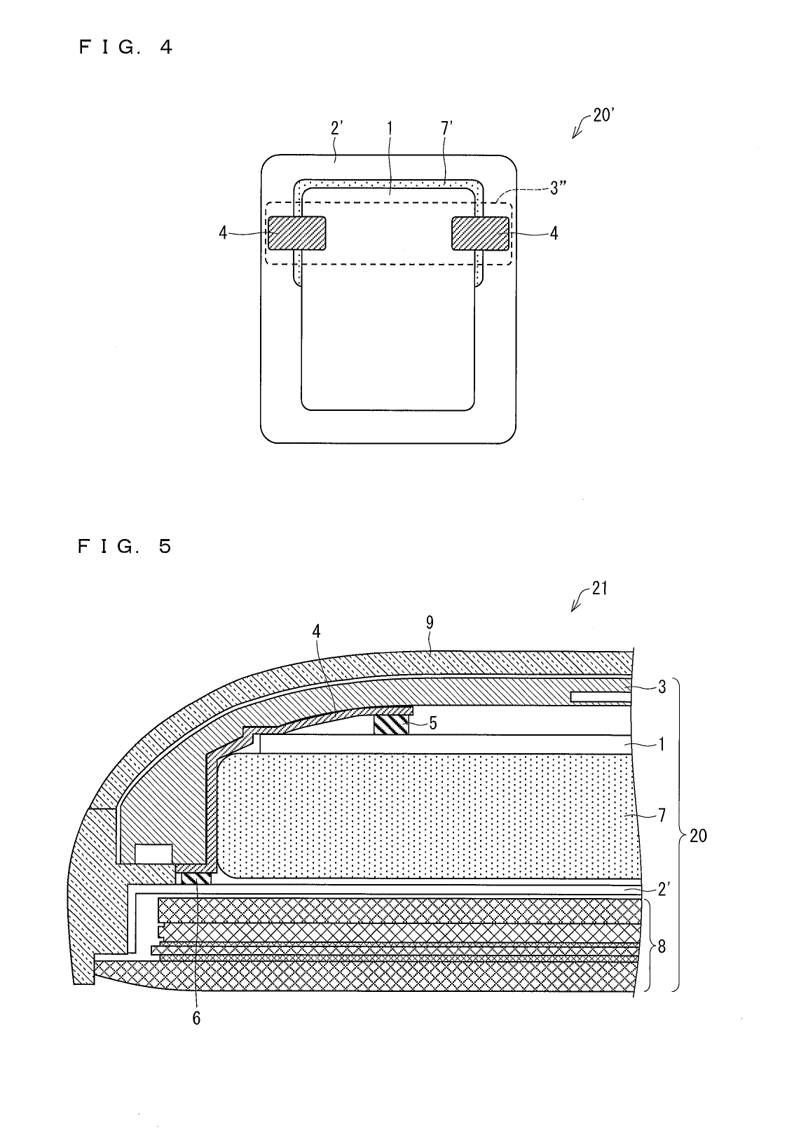

FIG. 4 shows another example of the structure in accordance with Embodiment 2. A structure 20′ illustrated in FIG. 4 includes the circuit board 1, the frame member 2′ which is electrically conductive, an insulator 3″ having no flexibility, the electrically conductive pattern 4 which is provided on the insulator 3″, and the battery (spacer member) 7′. In FIG. 4, the battery 7′, which is shaped so as to protrude out of an upper half of the circuit board 1, prevents the upper half of the circuit board 1 and an upper half of the frame member 2′ (an electrically conductive section) from facing each other. Note here that in FIG. 4, the insulator 3″ is provided so as to surround the upper half of the circuit board 1 and the upper half of the frame member 2′, and the electrically conductive pattern 4 electrically connects the upper half of the circuit board 1 and the upper half of the frame member 2′ (the electrically conductive section).

The structure 20′ thus includes the battery 7′, a part of which protrudes out of a space between the circuit board 1 and the frame member 2′. This allows the electrically conductive pattern provided on the insulator having no flexibility to suitably connect the circuit board 1 and the part of the frame member 2′ (the electrically conductive section) also in case where the circuit board 1 and the part of the frame member 2′ do not face each other.

### Application Example

FIG. 5 shows an example of a portable device including the structure 20 in accordance with Embodiment 2. As illustrated in FIG. 5, a portable device 21 includes the structure 20 and a cover 9 which covers the structure 20. The structure 20 in accordance with Embodiment 2 is thus suitably usable in the portable device 21.

As described earlier, also in a case where the battery 7, which prevents the circuit board 1 and the frame member 2′ from facing each other, is provided between the circuit board 1 and the frame member 2′, the electrically conductive pattern 4 provided on the housing 3 can electrically connect the circuit board 1 and the frame member 2′.

Further, use of the frame member 2′ as the electrically conductive section allows the circuit board 1 to be connected with a larger ground via the electrically conductive pattern 4. This allows more suitable stabilization of a reference electric potential of the circuit board 1.

In addition, also in Embodiment 2, an antenna pattern can be formed on the housing 3 as in Embodiment 1 by a method by which the electrically conductive pattern 4 of Embodiment 1 is formed.

### Embodiment 3

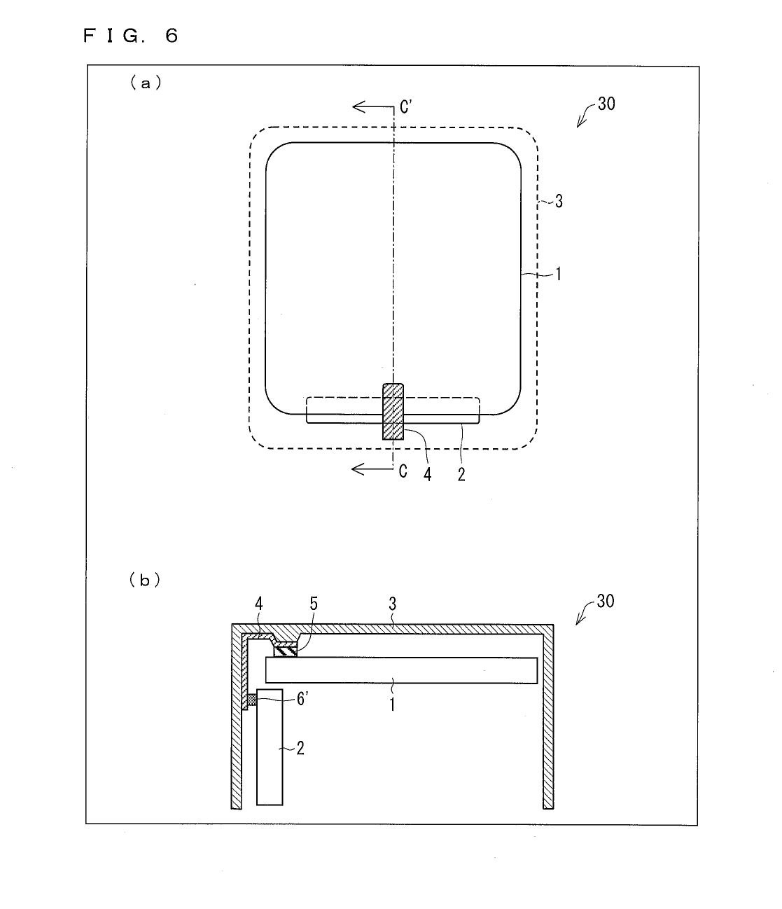

FIG. 6 shows an example of a structure in accordance with another embodiment (Embodiment 3) of the present invention. (a) of FIG. 6 is a top view of the structure, and (b) of FIG. 6 is a cross-sectional view taken from line C-C′ of (a) of FIG. 6. Note that, for convenience, members having functions identical to those of the respective members described in Embodiments 1 and 2 are given respective identical reference numerals, and a description of those members is omitted here.

As illustrated in (a) of FIG. 6 and (b) of FIG. 6, a structure 30 in accordance with Embodiment 3 includes a circuit board 1, a circuit board (electrically conductive section) 2, a housing (insulator) 3, an electrically conductive pattern 4, a gasket 5, and a spring 6′.

As illustrated in (b) of FIG. 6, the circuit board 1 and the circuit board 2 are provided so that a plane of the circuit board 1 and a plane of the circuit board 2 are at right angles. The circuit board 1 and the circuit board 2 which do not face each other as described above cannot be directly connected. Note that how to provide the circuit board 1 and the circuit board 2 is not limited to this. The circuit board 1 and the circuit board 2 only need to be provided so as to form an angle therebetween and so as not to face each other.

The structure 30 in accordance with Embodiment 3 causes the spring 6′ which is electrically conductive to connect the circuit board 2 and the electrically conductive pattern 4. Note that a member which connects the circuit board 2 and the electrically conductive pattern 4 is not limited to the spring 6′. For example, the member can be an electrically conductive gasket. Further, the structure 30 can be configured to directly connect the circuit board 2 and the electrically conductive pattern 4.

The electrically conductive pattern 4 is provided on the housing 3 by using the LDS method as in the case of Embodiments 1 and 2 to electrically connect the circuit board 1 and circuit board 2. Specifically, as illustrated in (b) of FIG. 6, the electrically conductive pattern 4 is provided on an inner side surface (a surface which faces the circuit board 2) of the housing 3 and an inner upper surface (a surface which faces the circuit board 1) of the housing 3.

The electrically conductive pattern 4 which has a three-dimensional shape as described above can also be more easily formed by the LDS method than by a method in which the electrically conductive pattern 4 is formed by attaching thereto copper foil or the like.

Further, also in Embodiment 3, an antenna pattern can be formed on the housing 3 as in Embodiment 1 by the method by which the electrically conductive pattern 4 of Embodiment 1 is formed.

### Embodiment 4

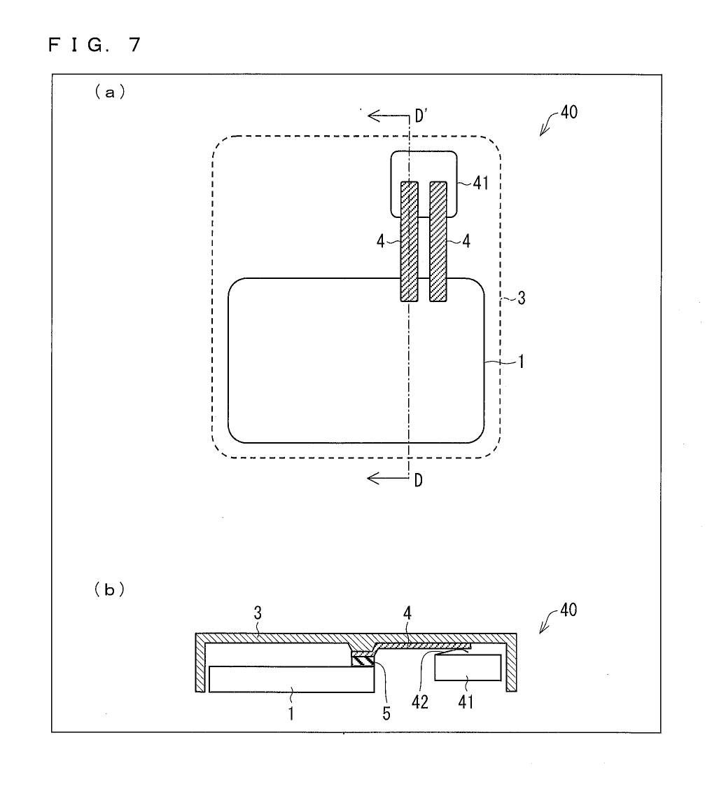

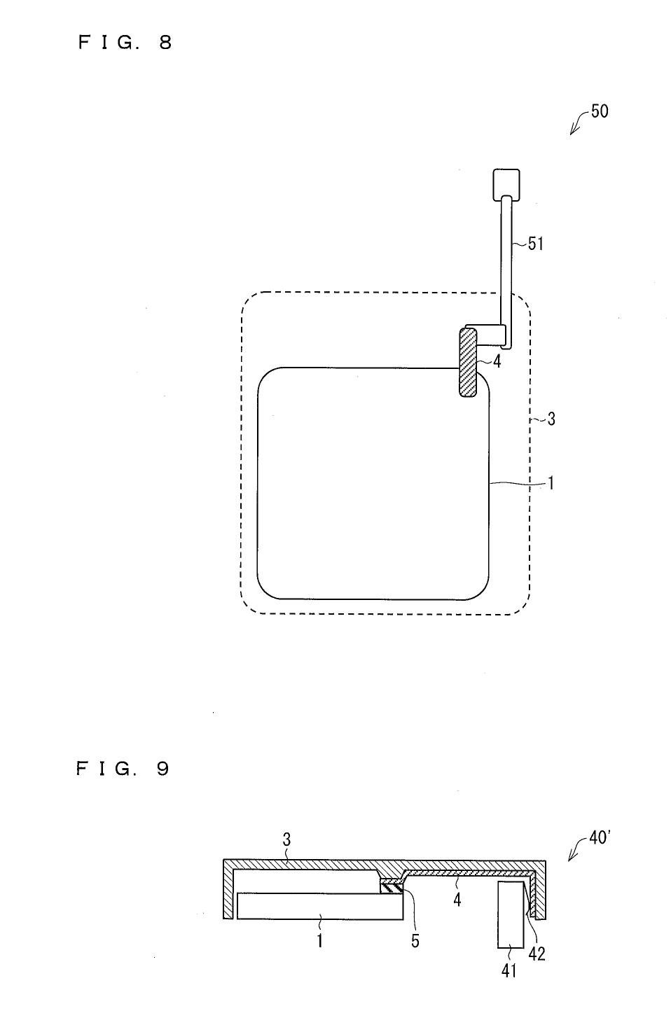

FIG. 7 shows an example of a structure in accordance with another embodiment (Embodiment 4) of the present invention. (a) of FIG. 7 is a top view of the structure, and (b) of FIG. 7 is a cross-sectional view taken from line D-D′ of (a) of FIG. 7. FIG. 8 and FIG. 9 each show another example of the structure in accordance with Embodiment 4. Note that, for convenience, members having functions identical to those of the respective members described in Embodiments 1 through 3 are given respective identical reference numerals, and a description of those members is omitted here.

As illustrated in (a) of FIG. 7 and (b) of FIG. 7, a structure 40 in accordance with Embodiment 4 includes a circuit board 1, a housing (insulator) 3, an electrically conductive pattern 4, a gasket 5, a vibrator (electrically conductive section) 41, and a connecting spring 42.

The structure 40 in accordance with Embodiment 4 is different from the structure 10 of Embodiment 1 in that the structure 40 includes the vibrator 41 instead of the circuit board 2. The vibrator 41 is an electrical component which is fixed on the housing 3 and is electrically conductive. The connecting spring 42 is a member for electrically connecting the vibrator 41 and the electrically conductive pattern 4. Note that a member for connecting the vibrator 41 and the electrically conductive pattern 4 is not limited to the connecting spring 42. A gasket or the like can also be used as the member.

The electrically conductive pattern 4 is provided on the housing 3 so as to electrically connect the circuit board 1 and the vibrator 41. The electrically conductive pattern 4 thus provided can connect the circuit board 1 and an electric wire of an electrical component such as the vibrator 41 which is provided so as to be away from the circuit board 1.

Note that an electrically conductive section of the present invention is not limited to the vibrator 41, which the above description takes as an example of the electrically conductive section. For example, the electrically conductive section can be an electrical component such as a speaker, or can be a whip antenna 51 of a structure 50 as illustrated in FIG. 8.

The electrically conductive section which includes an electrical component such as the whip antenna 51 is connected with the electrically conductive pattern 4 not only on an inner surface (a surface which faces the circuit board 1) of the housing 3 but also on an outer surface (a backside of the surface which faces the circuit board 1) of the housing 3.

The electrically conductive section which includes an electrical component such as the vibrator 41 is connected with the electrically conductive pattern 4 not only on an inner upper surface (a surface which faces the circuit board 1) of the housing 3 (see FIG. 7) but also on an inner side surface (a surface different from the surface which faces the circuit board 1) of the housing 3 (see FIG. 9).

Furthermore, also in Embodiment 4, an antenna pattern can be formed on the housing 3 as in Embodiment by the method by which the electrically conductive pattern 4 of Embodiment 1 is formed.

As described earlier, the circuit board 1 and the electrically conductive section, which is either an electrical component such as the vibrator 41 or an antenna such as the whip antenna 51, can be electrically connected via the electrically conductive pattern 4 as in the structure 40 or 50 of Embodiment 4.

### CONCLUSION

A structure in accordance with an aspect of the present invention includes a circuit board; an electrically conductive section (the circuit board 2, the frame member 2′, the vibrator 41, or the whip antenna 51) provided so as not to face the circuit board; and an electrically conductive pattern (the housing 3, or the insulator 3′ or 3″) provided on an insulator having no flexibility, the electrically conductive pattern electrically connecting the circuit board and the electrically conductive section.

The electrically conductive pattern provided on the insulator having no flexibility can be stretched with a high degree of freedom. Therefore, the configuration yields an effect of suitably electrically connecting the circuit board and the electrically conductive section also in a case where no other electrically conductive section (e.g., sheet metal, another circuit board, or electrical component) is provided so as to face the circuit board (e.g., in a case where a member such as a battery or a resin holder is provided between the circuit board and the electrically conductive section, in a case where the circuit board and the electrically conductive section are provided so as to be positionally displaced, or in a case where the circuit board and the electrically conductive section are provided so as to form an angle therebetween). Further, the circuit board and the electrically conductive section can be connected in a smaller space by use of the electrically conductive pattern than by use of copper foil, a flexible printed circuit board, a sheet metal, or the like.

The structure in accordance with an aspect of the present invention is preferably configured such that the electrically conductive pattern is formed by an LDS (Laser Direct Structuring) method.

According to the configuration, the electrically conductive pattern is provided by the LDS method. Therefore, the circuit board and the electrically conductive section can be connected in a smaller space and at lower cost in such a case than in a case where the circuit board and the electrically conductive section are connected by use of copper foil or the like. Further, it is possible to easily form an electrically conductive pattern which has a highly accurate shape that is difficult to make by use of copper foil or the like.

The structure in accordance with an aspect of the present invention is preferably configured such that the insulator is a housing.

According the configuration, in a case where the electrically conductive pattern is provided on the housing, which surrounds the circuit board and the electrically conductive section, it is possible to securely electrically connect the circuit board 1 and the circuit board 2 regardless of a positional relationship between the circuit board 1 and the circuit board 2. Further, also in a case where another member that is different from the circuit board 1 and the circuit board 2 is provided between the circuit board 1 and the circuit board 2, it is possible to securely electrically connect the circuit board 1 and the circuit board 2 by avoiding the another member.

The structure in accordance with an aspect of the present invention can be configured to further include a spacer member (the battery 7 or 7′), provided between the circuit board and the electrically conductive section, for preventing the circuit board and the electrically conductive section from facing each other.

According to the configuration, also in a case where the spacer member, which prevents the circuit board and the electrically conductive section from facing each other, is provided between the circuit board and the electrically conductive section, the electrically conductive pattern provided on the insulator can electrically connect the circuit board and the electrically conductive section.

The structure in accordance with an aspect of the present invention is preferably configured such that: the spacer member is a battery; the electrically conductive section is an electrically conductive frame member; and the circuit board and the electrically conductive section are ground connected via the electrically conductive pattern.

According to the configuration, also in a case where the battery is provided between the circuit board and the frame member so as to prevent the circuit board and the frame member from facing each other, the circuit board and the frame member can be suitably electrically connected by use of the electrically conductive pattern provided on the housing, so that a reference potential of the circuit board can be stabilized.

Conversely, in a case where the circuit board and the frame member are connected by use of the electrically conductive pattern provided on the housing, the battery provided between the circuit board and the frame member can have a size that is excessively large enough to prevent the circuit board and the frame member from facing each other. This allows an increase in capacitance of the battery.

The present invention is not limited to the description of the embodiments above, but may be altered by a skilled person within the scope of the claims. An embodiment based on a proper combination of technical means disclosed in different embodiments is encompassed in the technical scope of the present invention. Further, a new technical feature can be formed by combining technical measures disclosed in the embodiments.

### INDUSTRIAL APPLICABILITY

The present invention is usable in the field of production of electronic devices.

### REFERENCE SIGNS LIST

1 Circuit board
2 Circuit board (electrically conductive section)
2′ Frame member (electrically conductive section)
3 Housing (insulator)
3′, 3″ Insulator
4, 4′ Electrically conductive pattern
5 Gasket
6 Gasket
6′ Spring
7, 7′ Battery (spacer member)
8 LCD unit
9 Cover
10, 10′, 10″ Structure
20, 20′ Structure
21 Portable device
30 Structure
40, 40′ Structure
41 Vibrator (electrically conductive section)
42 Connecting spring
50 Structure
51 Whip antenna (electrically conductive section)

1-6. (canceled)

7. A structure comprising:
a circuit board;
an electrically conductive section provided so as not to face the circuit board; and
an electrically conductive pattern and an antenna pattern each provided on an insulator having no flexibility,
the electrically conductive pattern electrically connecting the circuit board and the electrically conductive section, and
the insulator being a housing.

8. The structure as set forth in claim 7, wherein the electrically conductive pattern and the antenna pattern are each formed by an LDS (Laser Direct Structuring) method.

9. A structure comprising:
a circuit board;
an electrically conductive section provided so as not to face the circuit board;
an electrically conductive pattern provided on an insulator having no flexibility; and
a spacer member, provided between the circuit board and the electrically conductive section, for preventing the circuit board and the electrically conductive section from facing each other,
the electrically conductive pattern electrically connecting the circuit board and the electrically conductive section,
the spacer member being a battery, and
the electrically conductive section being an electrically conductive frame member.

10. The structure as set forth in claim 9, wherein the circuit board and the electrically conductive section are ground connected via the electrically conductive pattern.

11. The structure as set forth in claim 9, wherein the electrically conductive pattern is formed by an LDS (Laser Direct Structuring) method.

12. The structure as set forth claim 9, wherein the insulator is a housing.

13. The structure as set forth in claim 7, wherein the electrically conductive pattern is a whip antenna.
